(19) United States
(12) Patent Application Publication
(10) Pub. No.: US 2003/0153119 A1
(43) Pub. Date: Aug. 14, 2003

(54) Integrated circuit package and method for fabrication

(76) Inventors: Richard J. Nathan, Morgan Hill, CA (US); Dale E. Means JR., Fremont, CA (US)

Correspondence Address: SILICON VALLEY PATENT GROUP LLP, 2350 MISSION COLLEGE BOULEVARD, SUITE 360, SANTA CLARA, CA, 95054, US

(21) Appl. No.: 10/077,211

(22) Filed: Feb. 14, 2002

(51) Int. Cl. H01L 21/44

(52) U.S. Cl. 438/106

(57) ABSTRACT

An integrated circuit package includes at least one semiconductor die embedded in a substrate made of a heat deformable material such as plastic or a combination of plastics. The at least one die is embedded so that the top surface of the at least one die, which contains a plurality of bonding pads, is exposed, and, in certain embodiments, substantially coplanar with the top surface of the substrate. A layer of conductive material is then formed on the top surface of the substrate and on the top surfaces(s) of at least one semiconductor die. This layer is formed into a plurality of electrically conductive paths each path beginning at a selected bonding pad and terminating in an electrically conductive land on the top surface of the substrate. Electrical connection is then made between the at least one die and external circuitry by placing the structure on a printed circuit board, for example, with electrically conductive balls between the electrically conductive lands on the substrate and adjacent electrical contacts on the printed circuit board. If desired, a protective coating can be formed over the at least one semiconductor die or over the combination of the at least one semiconductor die and the substrate to protect the surface of the at least one semiconductor die.

### FIELD OF THE INVENTION

This invention relates to semiconductor packages and in particular to a low cost package for one or more integrated circuit chips.

### BACKGROUND OF THE INVENTION

A package for an integrated circuit chip protects the integrated circuit chip (sometimes called a “die”), provides conductive leads for allowing electrical signals to be sent to (from) the outside world from (to) the integrated circuit die, and removes heat generated by electrical currents flowing in the circuitry formed in the die.

Satisfaction of these requirements can result in a sophisticated, complicated structure which is expensive to build and which affects the performance of the electrical circuits in the die within the package. There is a need for a semiconductor package which is both low cost and meets the above-described requirements for a semiconductor chip package.

### SUMMARY OF THE INVENTION

In accordance with this invention, an integrated circuit die package is provided which embeds at least one integrated circuit die in a substrate. The top surface of the at least one die is substantially coplanar with the top surface of the substrate. Conductive paths are formed from the at least one die to conductive contact points on the substrate. These paths allow electrical signals to be sent from (to) external circuitry to (from) the at least one die.

In one embodiment of the invention, at least one integrated circuit chip is embedded in a substrate with the top surface of the at least one integrated circuit chip being substantially coplanar to the top surface of the substrate. A single layer of conductive material, typically metal, is deposited on the top surface of the embedded substantially coplanar structure and patterned to form lands or bonding pads on the substrate as well as to form the interconnect to the aforementioned lands or pads on the substrate from bonding pads on the at least one embedded integrated circuit chip. A conductive plane over the at least one integrated circuit chip may also be formed from this single masking operation.

The location of the lands on the substrate may duplicate the footprint of a PQFP, PLCC or other conventional package such as a ball grid array so as to facilitate the use of the package of this invention in existing applications.

In an alternative embodiment, to enhance AC performance, a ground or Vcc plane is created over the at least one silicon die. Conductive traces, typically copper, are created from the respective pads on the silicon die to connect the plane to Vcc, ground, and/or an RF shield. This plane may be created during the same photo-masking operations that create the lands or pads on the substrate and the interconnecting traces as described above.

A dielectric which may be a solder mask or other plastic is formed over the top surface of the substrate so as to encapsulate the finished package, exposing only the lands or bonding pads on the substrate so that these lands may be electrically contacted by lead balls, direct copper connections, or other means. In some applications, similar openings may also be purposely created exposing geometrically defined areas of the ground or Vcc plane to allow the plane to be connected by lead balls, direct copper connections or other means.

As an alternative embodiment, following the placement of lands on the top side of the substrate, lands or bonding pads are created on the reverse side of the substrate so that they align with each of the lands on the top (i.e. front) side. Holes are then drilled mechanically or by laser through each of the lands on the front side and through the underlying substrate to form vias with the matching lands on the reverse (i.e. back) side of the substrate. The vias are then plated, preferably with copper but with any appropriate conducting metal to make them conductive, thus electrically connecting the coinciding front side lands with the backside lands.

In this alternative embodiment, the front and back sides are encapsulated with a solder mask or other plastic as described above with only the lands located on the back side of the substrate opposite the coplanar structure remaining exposed so that these lands may be electrically contacted by lead balls, direct copper, copper formed over a barrier metal such as chrome, connections, or other means to electrically conductive traces or contacts on a printed circuit board or other substrate.

As a feature of this invention, the conductive paths and conductive lands are formed from a single layer of conductive material such as copper or other appropriate metal using standard deposition and photolithographic techniques known in the semiconductor and printed circuit arts. This reduces the package cost while at the same time allowing great flexibility in the location of the electrical pads or lands for transmitting signals to and from the at least one embedded die.

In each of the embodiments described above, the edges of the at least one integrated circuit die can be either substantially perpendicular to the top surface of the die or can be beveled relative to the top surface of the die. Depending on the angle of the bevel, beveled surfaces either lock the embedded die in place in the underlying substrate or help center the die as it is being pressed into a depression or opening in the substrate.

In accordance with another embodiment of the invention, a protective coating is formed over the top surface of the at least one integrated circuit die to act as a barrier between the conductive material that is deposited over the coplanar structures and the die, and to protect at least one integrated circuit die from contaminants. This protective coating may be placed over the at least one integrated circuit die while the die are still part of a whole wafer, prior to sawing or other method of segmenting a silicon wafer into the individual die. Openings in the protective coating are then formed to expose the bonding pads on the silicon die to allow electrically conductive leads to be attached to these bonding pads.

In another embodiment, to prevent leakage currents around the edges of the at least one integrated circuit die, the at least one integrated circuit die is embedded in the substrate material such that the top surface(s) of the at least one integrated circuit die is (are) beneath the adjacent top surface of the substrate by a selected amount sufficient to ensure that the edges of the silicon die are embedded below the surface and completely surrounded by substrate material. Again, bonding pads on the top surface(s) of the at least one integrated circuit die are connected by conductive paths to lands or bonding pads formed on a selected surface. The lands or bonding pads on the substrate are, in some embodiments formed simultaneously with, and from the same conductive materials as the conductive paths. The resulting structure then can be applied directly to a printed circuit board by placing the exposed bonding pads on the substrate directly over corresponding contacts on the printed circuit board. Typically, solder balls formed on the bonding pads on the substrate allow electrical contact to be made between these bonding pads and the electrical contacts on the printed circuit board.

The die package of this invention is inexpensive to manufacture compared to prior art packages, provides a thinner package than in the prior art and controls impedance associated with the conductive leads interconnecting the die to the outside world.

This invention will be more fully understood in light of the following detailed description taken together with the following drawings.

### DESCRIPTION OF THE DRAWINGS

FIGS. 1a and 1b show in cross-section a semiconductor integrated circuit die embedded in a substrate of a heat moldable material such as a plastic or a combination of plastics to form a unitary integrated structure.

FIGS. 2a and 2b show the top view of the structure of FIG. 1 wherein an integrated circuit chip 21 with a plurality of bonding pads 22 formed on the top surface thereof has a plurality of conductive paths 23 leading from the integrated circuit chip bonding pads 22 to bonding pads 24 formed on the top surface of the substrate in which chip 21 is embedded.

FIGS. 3a and 3b show the structure of FIG. 2a and a cross-section of this structure, respectively, the cross-section showing the structure of FIG. 3a upside down ready to be mounted on a printed circuit board using solder balls 25 formed on top of bonding pads 24 to provide the electrical connection between the die 21 and the electrical circuitry on the printed circuit board.

FIGS. 4a and 4b show an embodiment of the invention wherein the integrated circuit chip 21 contains over the top surface thereof a protective layer 29.

FIGS. 5a and 5b show an embodiment of the invention wherein conductive lands or conductive pads are placed on the surface of the substrate opposite to the surface in which the die in mounted and conductive vias are formed through the substrate to connect the electrically conductive paths from the conductive pads on the top surface of the die to these conductive lands.

### DETAILED DESCRIPTION

The following detailed description is illustrative only and not limiting. Other embodiments of this invention will be obvious to those skilled in the art in view of this description.

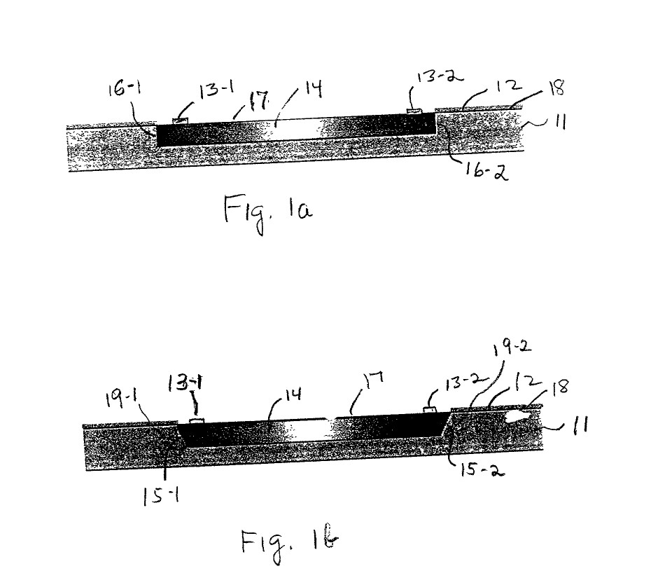

FIGS. 1a and 1b illustrate an integrated circuit chip 14 embedded in a substrate 11, typically of plastic, but of any other non-conductive material, including a combination of plastics, which is heat deformable and therefore capable of having die 14 pressed into material 11 when heated to form the structure shown in FIGS. 1a and 1b. More than one integrated circuit chip can be embedded in substrate 11, if desired. Die 14 has a top surface 17 on which are formed a plurality of electrically conductive bonding pads 13 of which bonding pads 13-1 and 13-2 are shown. Top surface 17 of die 14 is approximately coplanar with top surface 18 of substrate 11. Consequently, conductive leads such as conductive material 12 can be formed from a bonding pad such as pad 13-2 on the top surface of die 14 over the top surface of substrate 11 to end in a bonding pad (not shown) on substrate 11. Overlying the top surface 18 of substrate 11 and the top surface 17 of die 14 can be a protective layer of an overcoating material to protect the top surface of die 14 and the conductive leads 18 from moisture and other contaminants.

The silicon die 14 embedded in substrate 11 is placed in substrate 11 by heating substrate 11 until the plastic material making up substrate 11 is easily deformable and then pressing the die 14 gently into the plastic material until the top surface 17 of the die 14 is approximately coplanar with the top surface 18 of the substrate material 11. Techniques for doing this are described in copending U.S. patent application Ser. No. 09/963,337 filed Sep. 24, 2001 and assigned to JigSaw Tek, Inc., the assignee of this application. Application Ser. No. 09/963,337 is incorporated herein by reference in its entirety. The edges 16-1, 16-2 of die 14 in FIG. 1a are shown to be substantially perpendicular to the top surface of the integrated circuit die 14. However, die edges 15-1 and 15-2 in FIG. 1b are shown to be tapered either to allow die 14 to be more easily pressed into the flowable plastic material 11 or to lock the die 14 into the plastic substrate 11 once the plastic cools and solidifies. Dashed lines 19-1 and 19-2 in FIG. 1b show how the edges 15-1 and 15-2 can be tapered outward to lock die 14 in the substrate 11.

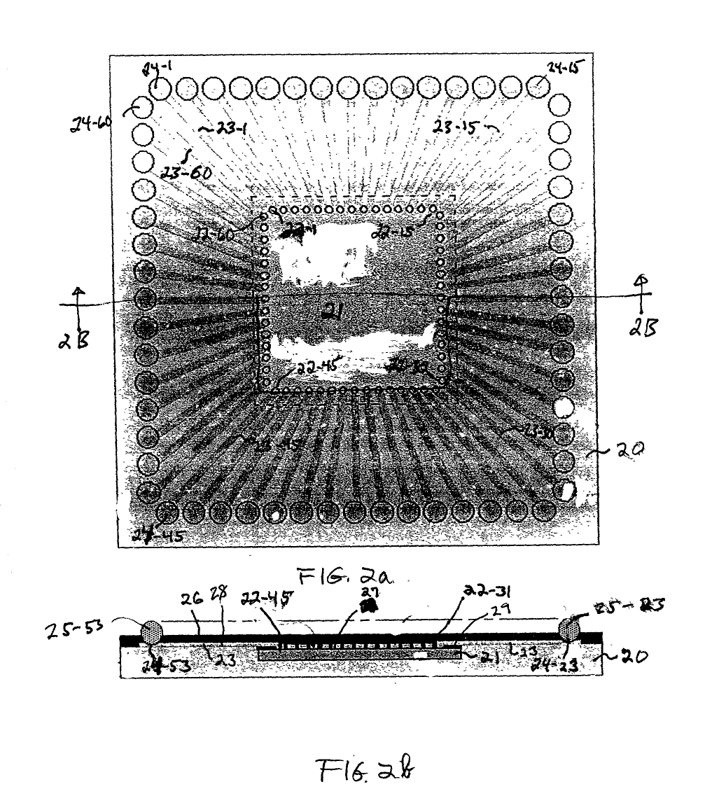

FIGS. 2a and 2b show a top view and cross-sectional side view, respectively, of an integrated circuit chip 21 embedded in substrate 20 in accordance with this invention. Of course, more than one integrated circuit chip 21 can be embedded in substrate 20 if desired. Die 21 has a plurality of bonding pads 22-1 through 22-60 formed on the top surface thereof in a well-known manner. The top surface 27 of die 21 as shown in cross-section FIG. 2b is slightly below the top surface 28 of substrate material 20. The fact that the top surface 27 of die 21 is slightly below the top surface 20 of substrate 20 allows a protective material 29 to be placed on top surface 27 of die 21 and have the top surface of the protective material be coplanar with the top surface of the substrate. However, the top surface 27 of die 21 is still considered to be substantially coplanar with the top surface 28 of the substrate material 20 even with this protective material 29 formed on the top surface 27 of die 21.

As shown in FIG. 2a, electrically conductive paths 23-1 through 23-60 are formed to connect each of the bonding pads 22-1 through 22-60, respectively, on the top surface 27 of die 21 to a corresponding one of bonding pads 24-1 through 24-60 on the top surface 28 of substrate material 20. Preferably bonding pads 24 are formed simultaneously with and from the same layer of material as electrically conductive paths 23. Bonding pads 24-1 through 24-60 can have formed on their top surfaces conductive balls 25-1 through 25-60 (of lead or other conductive material) to allow pads 24-1 through 24-60 to be electrically connected to electrically conductive traces on a substrate or printed circuit board to which the structure shown in FIGS. 2a and 2b will be functionally connected. The electrically conductive traces on the printed circuit board or substrate can then conduct the electrical signals from die 21 to other appropriate circuitry on the printed circuit board or substrate or from such other circuitry to die 21. Such other circuitry can include devices packaged as shown in FIGS. 2a and 2b or other more conventionally packaged structures, all within the discretion of the circuit designer.

As shown in application Ser. No. 09/963,337, die 21 is embedded in substrate material 20 by heating the substrate material 20 until material 20 is deformable and easily flowable and then pressing die 21 into the top surface of material 20.

Substrate 20 can be any appropriate plastic material or combination of plastic materials which is deformable by heating. The structure shown in FIG. 2b has formed over the top surface 27 of die 21 and the top surface 28 of substrate material 20 a plastic overcoating 26 to protect the top surface of die 21 and substrate material 20 from moisture and other contaminants which might affect the electrical performance of the die 21. Plastic coating 26 is formed after electrically conductive paths 23 and bonding pads or lands 24 have been formed on the top surface 28 of substrate material 20 to connect to bonding pads 22 on the top surface 27 of die 21. Openings are provided in coating 26 to expose the tops of lands 24. Coating 26 can also be formed of polyimide, any other appropriate polymer (including photosensitive polymers), or an appropriate insulating layer.

Conductive paths 23 and bonding pads 24 are typically formed using well-known photolithographic techniques. To do this, a layer of electrically conductive material, typically a metal such as copper, is deposited in any one of several well known ways (for example, by evaporation or sputtering) on the top surfaces 27 of die 21 and 28 of substrate material 20. This layer is then patterned to form the conductive paths 23 and bonding pads or lands 24 using photoresist and etching techniques, both well known in the art. Bonding pads 24 can be formed to match spatially the electrical contacts or leads on any one of several different package types (such as PQFP, PLCC or other conventional package type to allow the package of this invention to be used in place of such a conventional package with no change in the printed circuit board layout).

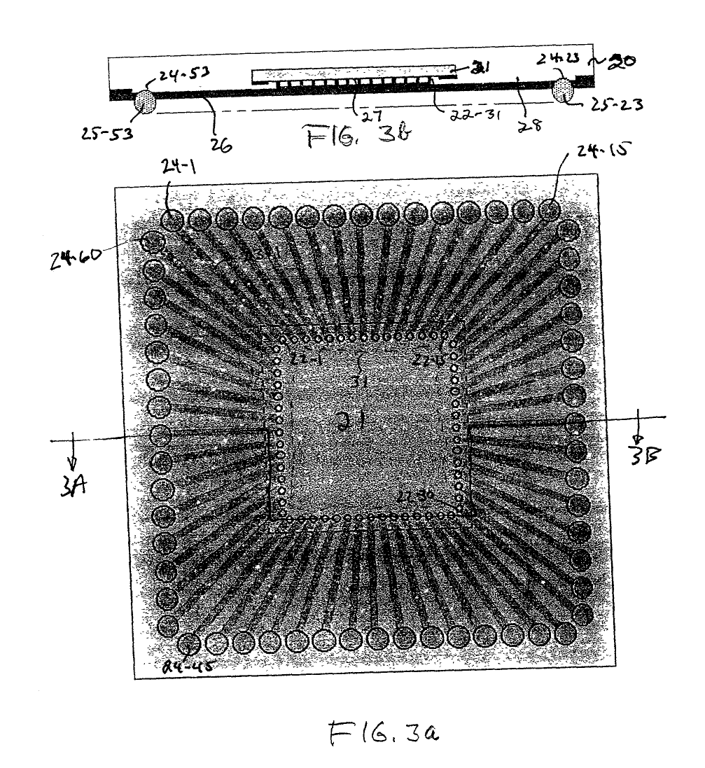

FIGS. 3a and 3b show the structure of FIGS. 2a and 2b with the cross-sectional view in FIG. 3b showing the semiconductor die 21 embedded in substrate material 20 (typically a plastic or a combination of plastics deformable at elevated temperatures) but with the resulting structure upside down ready to be mounted on a printed circuit board or substrate to interconnect the pads 22 on the top surface 27 of die 21 to the circuitry on the printed circuit board or substrate (neither of which are shown) using electrically conductive paths 23 from electrically conductive pads 22 to electrically conductive pads 24 on the top surface 28 of substrate 20. Lead solder balls 25 interconnect bonding pads 24 to other circuitry mounted on the printed circuit board or substrate.

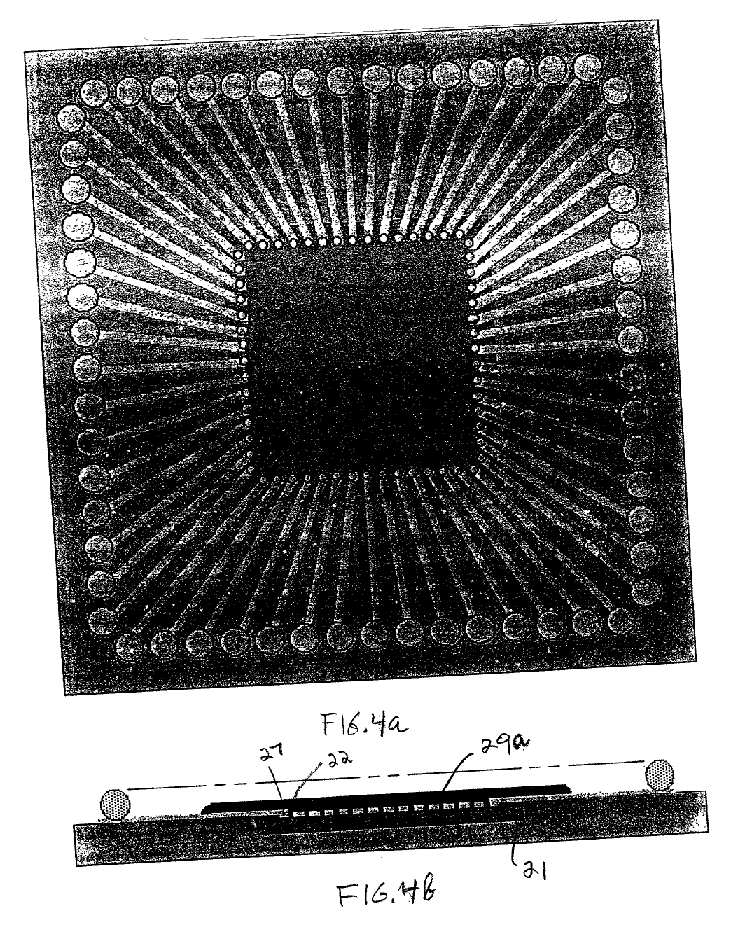

FIGS. 4a and 4b show the structure of FIGS. 2a, 2b, and 3a, 3b with a protective plastic coating 29 formed over the top surface 27 and bonding pads 22 on die 21. Plastic protective coating 29 prevents moisture and other contaminants from reaching the surface of die 21 and thereby protects the electrical performance of the die.

Traces 23 and pads or lands 24 in the structures described in FIGS. 2a, 2b, 3a, 3b and 4a, 4b typically can be of copper or any other appropriate conductive material, including composite layers of conductive materials. The conductive material is deposited by any appropriate technique in a manner so as not to adversely affect the underlying substrate. Formation of these traces from a single layer of conductive material such as metal using standard photolithographic techniques (i.e. masking the metal with photoresist, patterning the photoresist to expose the portions of the metal layer to be removed, removing the exposed metal, and then removing the masking photoresist to leave the resulting conductive paths and pads) will result in finely formed traces and lands of the type shown in the top views of FIGS. 2a, 3a and 4a. The partial plastic overcoat 29a in FIG. 4b contrasts with the fall plastic overcoat 26 shown in FIG. 2b. Both methods are commercially used today to protect integrated circuits contained within a package.

Referring, for example, to FIGS. 2a, 3a, and 4a, the silicon die 21 shown in these figures can have formed thereon a coating of electrically conductive material over its top surface. Such a coating would be formed in the boundary shown in FIG. 3a by the dashed lines 31 to provide a ground plane or a VCC plane. Such a plane can function either as an isolator or an RF shield. Selected portions of such a conductive layer would be connected to selected one or more of bonding pads 22-1 through 22-60 to provide the desired electrical bias. In an alternative embodiment, not shown in the drawing, a protective coating (such as coating 26 as described above) is formed over the conductive plane, a plurality of openings are created in coating 26 over the plane to allow solder balls to be attached, or direct copper connections to be made to the plane. These connections may be used to electrically connect the plane to an external substrate such as a printed circuit board, provide added mechanical strength and can also be utilized to provide thermal paths for removing heat from the integrated circuit.

As an alternative embodiment, not shown in any of the drawings, a layer of electrically conductive material may be formed on the side opposite the silicon die, and may or may not be electrically connected to ground or Vcc, and may provide additional thermal conduction or RF shielding. This plane may be in addition to a plane formed on the same side as the silicon die.

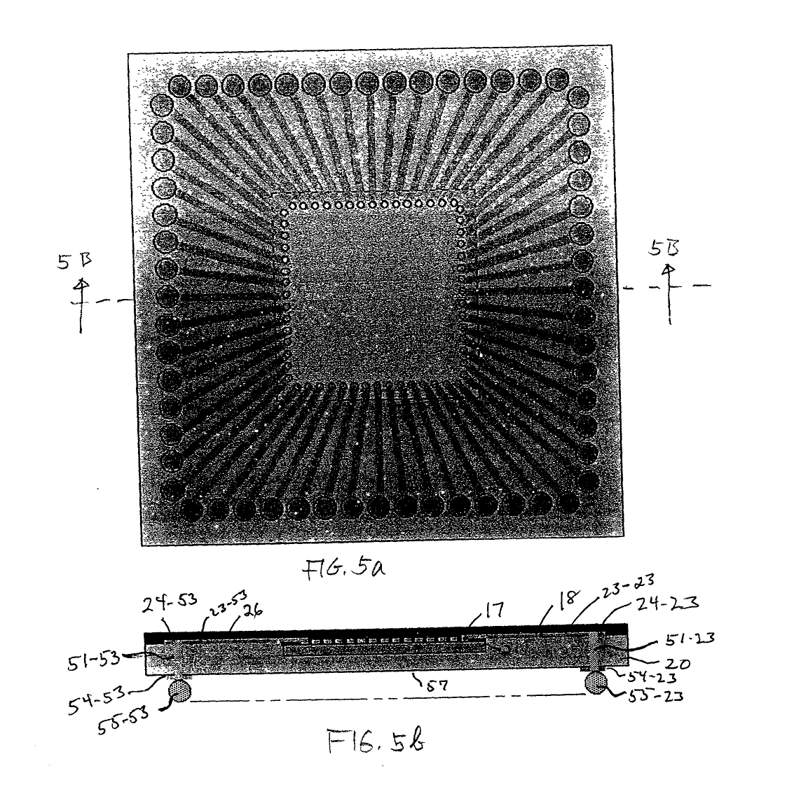

FIGS. 5a and 5b shown an alternative embodiment of this invention wherein integrated circuit die 21 is embedded in substrate material 20 (typically plastic or a combination of plastics, all heat deformable to allow die 21 to be pressed into the substrate material 20), together with vias 51-1 through 51-60 (of which only 51-23 and 51-53 are shown) formed through substrate material 20 to allow the packaged integrated circuit die 21 to be mounted on a printed circuit board with the top surface 17 of die 21 facing outward from the printed circuit board. Bonding pads 54-1 through 54-60 are formed on the bottom surface 57 of substrate material 20 and solder balls 55-1 through 55-60 are then formed on the corresponding ones of bonding pads 54-1 through 54-60 to allow the structure to be interconnected to an underlying PC board. Vias 51-1 through 51-60 (of which vias 51-23 and 51-53 are shown in cross-section FIG. 5b) are formed in any one of several ways. Typically, such vias can be formed by burning openings through conductive material 20 with a laser or forming such openings with a mechanical drill at the selected points where the vias 51 are to be present and then filling these vias using electroless plating with an electrically conductive material such as copper. Then, following the formation of the vias, the top surface 17 of integrated circuit die 21 and the top surface 18 of substrate 20 have formed thereon conductive paths 23 in the manner described above in conjunction with FIGS. 2a, 3a and 4a. A protective coating 26 is formed over the top surface of both die 21 and substrate 20 to protect both the die and the electrically conductive leads 23 (of which only conductive leads 23-3 and 23-53 are shown in cross-section in FIG. 5b) from moisture and other contaminants which might interfere with the electrical performance of the circuitry. Such interference can come about in a number of ways including the formation of conductive paths between adjacent conductive leads or the corrosion of conductive paths due to the presence of unwanted contamination.

The semiconductor package of this invention is simple and inexpensive to make. The use of a single layer of electrically conductive materials to form conductive paths and lands on the surface of the composite substrate-die structure yields a rugged inexpensive, ultra-thin structure. The structure of this invention is essentially a planar structure. Therefore, two or more such structures can be stacked one on top of the other with appropriate connections being formed between the stacked packages to allow multichip modules to be fabricated with a small footprint in compact volumes.

The integrated circuit chip or die used with the disclosed structure will typically be silicon but could also be of any other semiconductor material such as gallium arsenide or germanium. An advantage of this invention is that die of the same or different materials can be included in one package and interconnected to each other and the outside world by conductive traces formed as described above. Of course, a conductive trace connecting two die would run from a bonding pad on the top surface of one die to a bonding pad on the top surface of the other die.

Unless otherwise specified, the term “conductive” as used herein means “electrically conductive.” An electrically conductive material can also conduct heat and in certain embodiments serves that function as well, as described above.

While several embodiments of this invention have been described, other embodiments of this invention will be obvious in view of this disclosure.

What is claimed is:

1. Structure comprising:
a substrate formed of a heat deformable material;
at least one semiconductor die embedded in said substrate such that the top surface(s) of said at least one semiconductor die and the top surface of said substrate are in substantially the same plane;
a plurality of bonding pads formed on the top surface(s) of said at least one die; and
a plurality of conductive paths formed over the top surface(s)of said at least one die and the top surface of said substrate, each conductive path ending on the top surface of said substrate in a conductive land or pad and beginning in electrical contact with a corresponding bonding pad on said at least one die thereby to connect said corresponding bonding pad on the top surface(s) of said at least one die with a corresponding conductive land or pad on the top surface of said substrate.

2. Structure as in claim 1 including a plurality of conductive balls, each ball being formed on a corresponding one of the conductive lands or pads on the top surface of said substrate, said conductive balls allowing said structure to be electrically connected to electrical contacts on an additional substrate.

3. Structure as in claim 2 wherein said additional substrate is a printed circuit board.

4. Structure as in claim 3 wherein said printed circuit board includes electrically conductive traces connected to said electrical contacts thereby to allow electrical signals to be sent from said at least one die to circuitry external to said at least one die and to also allow electrical signals to be sent from circuitry external to said at least one die to said at least one die.

5. Structure as in claim 1 wherein the top surface(s) of said at least one die is (are) protected by a protective coating thereby to prevent contaminants or moisture from reaching the top surface(s) of said at least one die and to act as a barrier between the semiconductor material and the conductive paths.

6. Structure as in claim 5 wherein said protective coating is selected from the group of materials consisting of plastic, polyimide and other photosensitive polymers.

7. Structure as in claim 5 wherein said protective coating covers the top surface(s) not only of said at least one die but also of said substrate.

8. Structure as in claim 1 including
a second set of bonding pads on a bottom surface of said substrate opposite to the top surface of said substrate; and
a set of conductive vias in said substrate, each conductive via connecting one of the bonding pads on the bottom surface of said substrate to a corresponding bonding pad on the top surface of said substrate.

9. The method of fabricating a package for at least one semiconductor die which comprises:
forming a substrate of a material deformable at a temperature elevated relative to room temperature;
heating said substrate until the substrate material is deformable;
pressing at least one semiconductor die into said substrate until the top surface of said at least one semiconductor die occupies a selected position relative to the top surface of said substrate; and
cooling said substrate thereby to embed said integrated circuit die in said substrate material.

10. The method of claim 9 wherein the step of cooling said substrate comprises allowing said substrate to cool in a room temperature or specifically controlled temperature environment.

11. The method of claim 9 including the step of forming at least one conductive path on the top surface(s) of said at least one semiconductor die and substrate, said at least one conductive path terminating in a conductive land on the top surface of said substrate thereby to interconnect a bonding pad on the top surface(s) of said at least one semiconductor die to said conductive land.

12. The method of claim 9 wherein the at least one semiconductor die is pressed into said deformable substrate material until the top surface(s) of said at least one semiconductor die is (are) substantially coplanar with the top surface of said substrate.

13. The method of claim 11 wherein the step of forming said at least one conductive path and conductive land connected to a bonding pad on the top surface of said at least one semiconductor die comprises:
forming a layer of conductive material on the top surface(s) of said at least one semiconductor die and said substrate; and
forming said layer of conductive material into said at least one conductive path and said conductive land connected to one end of said conductive path.

14. The method of claim 13 wherein forming said layer of conductive material into said at least one conductive path comprises forming said layer of conductive material into a plurality of conductive paths and lands, each path terminating on top of said substrate as a conductive land.

15. The method of claim 9:
wherein the at least one semiconductor die contains a plurality of bonding pads on said top surface(s) of said at least one semiconductor die; and
wherein each conductive path between one of said bonding pads on the top surface(s) of said at least one semiconductor die terminates in a conductive land on the top surface of said substrate.

16. The method of claim 13 wherein each of the conductive paths terminating in a conductive land is formed by
providing a conductive layer on the top surface of the structure; and
patterning said conductive layer into a plurality of conductive paths and conductive lands using photolithographic techniques.

17. The method of claim 13 including:
forming at least one conductive land on a bottom surface of said substrate opposite said top surface; and
forming at least one conductive via from the at least one conductive land on the bottom surface of said substrate to the at least one conductive land on the top surface of said substrate.

18. Structure as in claim 1, including:
at least one conductive plane formed over at least a portion of at least one top surface of said at least one die, said conductive plane being electrically insulated from selected ones of said plurality of bonding pads formed on the top surface of said at least one die.

19. Structure as in claim 18 wherein said conductive plane is formed in a region interior to said plurality of bonding pads on at least one top surface of said at least one die.

20. Structure as in claim 19 wherein said conductive plane is connected to one or more selected electrical contacts so as to be capable of providing a voltage from the group of voltages consisting of ground and Vcc.

21. Structure as in claim 19 wherein said conductive plane has at least one connection to at least one of the bonding pads formed on the at least one top surface of said at least one die thereby to allow a selected potential to be applied to said conductive plane.

22. Structure as in claim 18 wherein:
said at least one conductive plane has formed over the top surface thereof a protective coating of an insulating material;
at least one opening is formed through said protective coating of insulating material to expose a portion of the top surface of said conductive plane; and
a conductive material is placed in said opening to allow both electrical connection to be made to said conductive plane and to allow heat to be transferred from said conductive plane.

23. Structure as in claim 22 wherein:
said protective coating has a plurality of openings formed in the top surface thereof and a plurality of conductive materials formed in said corresponding plurality of openings, each conductive material in a selected opening being capable of providing electrical connection to said conductive plane and allowing heat to be transferred from said conductive plane to an external sink or substrate.

24. Structure as in claim 23 wherein:
said conductive material comprises lead balls formed in each of said openings in said protective coating, said lead balls being capable of being connected to a printed circuit board, thereby to allow electrical potential to be applied to said conductive plane and heat to be transferred from said conductive plane.

25. Structure as in claim 18, including:
a bottom electrically conductive plane formed on the surface of said substrate opposite said top surface.

26. Structure as in claim 25, including:
at least one electrically conductive connection formed to connect said bottom electrically conductive plane to a source of electrical potential.

27. Structure as in claim 26 wherein said source of electrical potential is selected from a group of voltage sources capable of providing ground and Vcc.

28. Structure comprising:
a substrate formed of a heat deformable materials;
a semiconductor die embedded in said substrate such that the top surface of said semiconductor die and the top surface of said substrate are both exposed;
a plurality of bonding pads formed on the top surface of said semiconductor die; and
a plurality of conductive paths formed over the top surface of said semiconductor die and over the top surface of said substrate, each conductive path ending on said top surface of said substrate as a conductive land, and beginning on said semiconductor die in electrical contact with one of said plurality of bonding pads.

29. Structure as in claim 20 wherein:
the top surface of said semiconductor die and the top surface of said substrate are substantially coplanar.
